(19) United States
(12) Patent Application Publication
(10) Pub. No.: US 2009/0126922 A1
(43) Pub. Date: May 21, 2009

(54) Heat transfer device

(76) Inventor: Jan Vetrovec, Larkspur, CO (US)

Correspondence Address: Aqwest LLC, P.O. BOX 468, Larkspur, CO, 80118, US

(21) Appl. No.: 12/290,195

(22) Filed: Oct. 28, 2008

Related U.S. Application Data
(60) Provisional application No. 61/000,855, filed on Oct. 29, 2007.
(60) Provisional application No. 61/191,304, filed on Sep. 8, 2008.

(51) Int. Cl. F28F 7/00; H01L 33/00; H01S 5/024; H01L 23/34

(52) U.S. Cl. 165/185; 257/79; 372/43.01; 257/714; 257/E33.056; 257/E23.08

(57) ABSTRACT

The invention is for an apparatus and method for removal of waste heat from heat-generating components including high-power solid-state analog electronics such as being developed for hybrid-electric vehicles, solid-state digital electronics, light-emitting diodes for solid-state lighting, semiconductor laser diodes, photo-voltaic cells, anodes for x-ray tubes, and solids-state laser crystals. Liquid coolant is flowed in one or more closed channels having a substantially constant radius of curvature. Suitable coolants include electrically conductive liquids (including liquid metals) and ferrofluids. The former may be flowed by magneto-hydrodynamic effect or by electromagnetic induction. The latter may be flowed by magnetic forces. Alternatively, an arbitrary liquid coolant may be used and flowed by an impeller operated by electromagnetic induction or by magnetic forces. The coolant may be flowed at very high velocity to produce very high heat transfer rates and allow for heat removal at very high flux.

### CROSS-REFERENCE TO RELATED APPLICATIONS

This application claims priority from U.S. provisional patent application U.S. Ser. No. 61/000,855, filed on Oct. 29, 2007; and U.S. provisional patent application U.S. Ser. No. 61/191,304, filed on Sep. 8, 2008.

### FIELD OF THE INVENTION

This invention relates generally to heat removal from heat-generating components and more specifically to heat removal at high heat flux.

### BACKGROUND OF THE INVENTION

The subject invention is an apparatus and method for removal of waste heat from heat-generating components including analog solid-state electronics, digital solid-state electronics, semiconductor laser diodes, light emitting diodes, photo-voltaic cells, vacuum electronics, and solid-state laser crystals.

There are many devices generating waste heat as a byproduct of their normal operations. These include analog solid-state electronic components, digital solid-state electronic components, semiconductor laser diodes, light emitting diodes for solid-state lighting, solid-state laser components, laser crystals, vacuum electronic components, and photovoltaic cells. Waste heat must be efficiently removed from such components to prevent overheating and consequential loss of efficiency, malfunction, or even catastrophic failure. Methods for waste heat management may include conductive heat transfer, convective heat transfer, and radiative heat transfer, or various combinations thereof. For example, waste heat removed from heat generating components may be transferred to a heat sink by a flowing heat transfer fluid. Such a heat transfer fluid is also known as a coolant.

Cooling requirements for the new generation of heat-generating components (HGC) are very challenging for thermal management technologies of prior art. For example, an ongoing miniaturization of semiconductor digital and analog electronic devices requires removal of heat at ever increasing fluxes now on the order of several hundreds of watts per square centimeter. Traditional heat sinks and heat spreaders have large thermal resistance contributing to elevated junction temperatures and thus reducing device reliability. As a result, removal of heat often becomes the limiting factor and a barrier to further performance enhancements. More specifically, a new generation of high-power semiconductors for hybrid electric vehicles and future plug-in hybrid electric vehicles requires improved thermal management to boost heat transfer rates, eliminate hot spots, and reduce volume, while allowing for higher current density.

High-brightness light emitting diodes (LED) being developed for solid-state lighting for general illumination in commercial and household applications also require improved thermal management. These new light sources are becoming of increased importance as they offer up to 75% savings in electric power consumption over conventional lighting systems. Waste heat must be effectively removed from the LED chip to reduce junction temperature, thereby prolonging LED life and making LED cost effective over traditional lighting sources.

Another class of electronic components requiring improved cooling are semiconductor-based high-power laser diodes used for direct material processing and pumping of solid-state lasers. Generation of optical output from laser diodes is accompanied by production of large amount of waste heat that must be removed at a flux on the order of several hundreds of watts per square centimeter. In addition, the temperature of high-power laser diodes must be controlled within a narrow range to avoid undesirable shifts in output wavelength.

Photovoltaic cells (solar electric cells and thermo-photovoltaic cells) are becoming increasingly important for generation of electricity. Such cells may be used with concentrators to increase power generation per unit area of the cell and thus reduce initial installation cost. This approach requires removal of waste heat at increased flux. Similarly, high-performance crystals used in solid-state lasers generate waste heat that may require removal at fluxes in the neighborhood of thousand watts per square centimeter.

Anodes in x-ray tubes are subjected to very high thermal loading. Rotating anodes are frequently used to spread the heat to avoid overheating. Such rotating anodes inside a vacuum enclosure are impractical for use in a new generation of x-ray tubes for use in compact and portable devices in medical and security applications. A compact and lightweight heat transfer component having no moving parts inside the vacuum is very desirable.

Current approaches for removal of waste heat for at high fluxes include 1) spreading of heat with elements having high thermal conductivity and/or 2) forced convection cooling using liquid coolants. However, even with heat spreading materials having extremely high thermal conductivity such as diamond films and certain graphite fibers, a significant thermal gradient is required to conduct large amount of heat even over short distances. In addition, passive heat spreaders are not conducive to temperature control of the HGC. Forced convection methods for removal of waste heat at high fluxes may use microchannel heat exchangers or impingement jets to obtain desirable heat transfer coefficient with conventional coolants such as water, alcohol, or ethylene glycol. Liquid metal coolants have been also considered to attain target heat transfer coefficient. Known forced convection systems have many components, are bulky, heavy, and have geometries that require the coolant to make complex directional changes while traversing the coolant loop. Such directional changes are a potential source of increased flow turbulence causing higher pressure drop in the loop and, therefore, necessitate higher pumping power.

In summary, prior art does not teach a heat transfer device capable of removing heat at very high fluxes that is also compact, lightweight, self contained, capable of accurate temperature control, has a low thermal resistance, and requires very little power to operate. It is against this background that the significant improvements and advancements of the present invention have taken place.

### SUMMARY OF THE INVENTION

The present invention provides a heat transfer device (HTD) wherein a coolant flows in a closed channel with a substantially constant radius of curvature. This arrangement offers low resistance to flow, which allows to flow the coolant at very high velocities and thus enables heat transfer at very high rate while requiring relatively low power to operate. HTD of the subject invention may be used to cool HGC requiring removal of waste heat at very high heat flux. Such HGC may include solid-state electronic chips, semiconductor laser diodes, light emitting diodes for solid-state lighting, solid-state laser components, laser crystals, optical components, vacuum electronic components, and photovoltaic cells. Heat removed by HTD from HGC may be transferred to a heat sink or environment at a reduced heat flux. For example, HTD may transfer acquired heat to a structure, heat pipe, secondary liquid coolant, phase change material (PCM), gaseous coolant, or ambient air.

In one preferred embodiment of the present invention, the HTD comprises a body having a first surface, a second surface, and a closed flow channel. The first surface is adapted for receiving heat from a heat generating component and the second surface is adapted for transferring heat to a heat sink. The flow channel has a substantially constant radius of curvature in the flow direction. An electrically conductive liquid coolant is flowed inside the flow channel by means of a magneto-hydrodynamic (MHD) effect (MHD drive).

In another preferred embodiment of the present invention, electrically conductive liquid or ferrofluid coolant may be used and flowed by the means of a moving magnetic field. Moving magnetic field induces eddy currents in the electrically conductive coolant that, in turn, provide force coupling to the coolant (inductive drive). Alternatively, moving magnetic field directly couples into the ferrofluid (magnetic drive). Suitable moving field may be generated by a rotating magnet.

In yet another preferred embodiment of the present invention, the moving (rotating or traveling magnetic) magnetic field may be generated by stationary electromagnets operated by alternate current in an appropriate poly-phase relationship. In a still another embodiment of the present invention, the coolant is an arbitrary liquid flowed in a closed channel with a substantially constant radius of curvature. The coolant flow is induced by a rotating impeller (impeller drive) spun by a flow of secondary coolant, mechanical means, moving magnetic field, or by electromagnetic induction.

Accordingly, it is an object of the present invention to provide a heat transfer device (HTD) for removing waste heat from HGC. The HTD of the present invention is simple, compact, lightweight, self-contained, can be made of materials with a coefficient of thermal expansion (CTE) matched to that of the HGC, requires relatively little power to operate, and it is suitable for large volume production.

It is another object of the invention to provide means for cooling HGC.

It is still another object of the invention to provide means for temperature control of HGC.

It is yet another object of the invention to cool a semiconductor electronic components.

It is yet further object of the invention to cool semiconductor laser diodes.

It is a further object of the invention to cool LED for solid-state lighting.

It is still further object of the invention to cool computer chips.

It is an additional object of the invention to cool photovoltaic cells.

These and other objects of the present invention will become apparent upon a reading of the following specification and claims.

### BRIEF DESCRIPTION OF THE DRAWINGS

FIG. 1A is a side cross-sectional view of a heat transfer device (HTD) in accordance with one embodiment of the subject invention using a magneto-hydrodynamic drive.

FIG. 1B is a cross-sectional view of an HTD in a plane transverse to coolant flow in accordance with one embodiment of the subject invention using a magneto-hydrodynamic drive.

FIG. 2A is an enlarged view of portion 2A of the HTD of FIG. 1A.

FIG. 2B is an enlarged view of portion 2B of the HTD of FIG. 1B.

FIG. 3 is an enlarged view of alternative portion 2B of the HTD of FIG. 1B showing a flow channels with surface extensions.

FIG. 4 is an enlarged view of another alternative portion 2B of the HTD of FIG. 1B showing multiple flow channels arranges side-by-side.

FIG. 5 is an enlarged view of portion 2A of the HTD of FIG. 1A showing a mounting of a laser diode array HGC.

FIG. 6 is an enlarged view of portion 2A of the HTD of FIG. 1A showing a mounting of a laser diode bar HGC.

FIG. 7 is an enlarged view of portion 2A of the HTD of FIG. 1A showing a mounting of a light emitting diode HGC.

FIG. 8 is an enlarged view of portion 2A of the HTD of FIG. 1A showing a mounting of a solid-state laser crystal HGC.

FIG. 9 shows an alternative HTD body having internal passages for a Secondary coolant.

FIG. 10 shows another alternative HTD body having external fins for heat transfer to gaseous coolant or ambient air.

FIG. 11A is a side cross-sectional view of an HTD in accordance with another embodiment of the subject invention wherein coolant flow is induced by a rotating magnetic field produced by a rotating magnet.

FIG. 11B is a side cross-sectional view of an HTD in a plane transverse to coolant flow in accordance with another embodiment of the subject invention wherein coolant flow is induced by a rotating magnetic field produced by a rotating magnet.

FIG. 12A is a side cross-sectional view of an HTD in accordance with a yet another embodiment of the subject invention wherein coolant flow is induced by a rotating magnetic field produced by stationary electromagnets.

FIG. 12B is a side cross-sectional view of an HTD in a plane transverse to the flow loop in accordance with yet another embodiment of the subject invention wherein coolant flow is induced by a rotating magnetic field produced by stationary electromagnets.

FIG. 13 shows a suitable connection of electromagnets to a single phase alternating current supply.

FIG. 14 shows a variant to the HTD in accordance with a yet another embodiment of the subject invention wherein the electromagnets are arranged to generate translating magnetic field.

FIG. 15A is a side cross-sectional view of an HTD in accordance with still another embodiment of the subject invention using an impeller.

FIG. 15B is a side cross-sectional view of an HTD in a plane transverse to coolant flow in accordance with still another embodiment of the subject invention using an impeller.

FIG. 16A is a plan view of an HTD in accordance with a further embodiment of the subject invention having a planar flow loop.

FIG. 16B is a side cross-sectional view of an HTD in accordance with further embodiment of the subject invention having a planar flow loop.

FIG. 17A is a plan view of an HTD in accordance with a still further embodiment of the subject invention having a planar flow loop with an impeller.

FIG. 17B is a side cross-sectional view of an HTD in accordance with still further embodiment of the subject invention having a planar flow loop with an impeller.

FIG. 18 is a plan view of an alternative impeller of the HTD of FIG. 17A.

FIG. 19A is a side cross-sectional view of an HTD in accordance with a yet further embodiment of the subject invention having an elongated flow loop.

FIG. 19B is a face view of an HTD in accordance with yet further embodiment of the subject invention having an elongated flow loop.

### DETAILED DESCRIPTION OF THE PREFERRED EMBODIMENTS

Selected embodiments of the present invention will now be explained with reference to drawings. In the drawings, identical components are provided with identical reference symbols in one or more of the figures. It will be apparent to those skilled in the art from this disclosure that the following descriptions of the embodiments of the present invention are merely exemplary in nature and are in no way intended to limit the invention, its application, or uses.

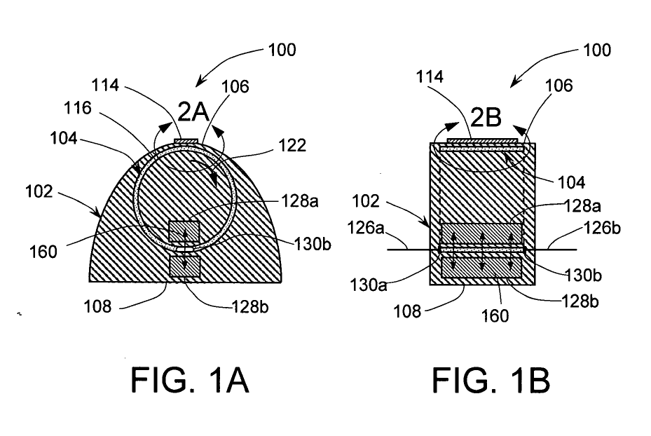

Referring now to FIGS. 1A and 1B, there is shown a heat transfer device (HTD) 100 in accordance with one preferred embodiment of the subject invention. HTD 100 comprises a body 102, magnets 128a and 128b, electrodes 130a and 130b, and electric conductors 126a and 126b. The body 102 further comprises a first surface 106 adapted for receiving heat from a heat generating component (HGC), a second surface 108 adapted for rejecting heat to a heat sink, and a flow channel 104. The body 102 is preferably made of material having high thermal conductivity. Preferably, such a material may also have a low electrical conductivity or such a material may be dielectric. Suitable materials for construction of the body 102 may include silicon, berylia, and silicon carbide. A heat generating component (HGC) 114 may be also attached to the first surface 106 and arranged to be in a good thermal contact therewith. HGC 114 may be, but it is not limited to a solid-state electronic chip, semiconductor laser diode, light emitting diodes (LED), solid-state laser crystal, optical component, x-ray tube anode, or a photovoltaic cell. If desired, the body 102 may be made from material having a coefficient of thermal expansion (CTE) matched to the CTE of the HGC 114. The second surface 108 is arranged to be in a good thermal communication with a heat sink. Suitable heat sinks include a structure, heat pipe, secondary liquid coolant, phase change material (PCM), gaseous coolant, or ambient air. Fluid used as a heat sink may employ natural convection or forced convection to remove heat from the second surface 108. The second surface 108 may also include surface extensions such as fins or ribs to enhance heat transfer therefrom.

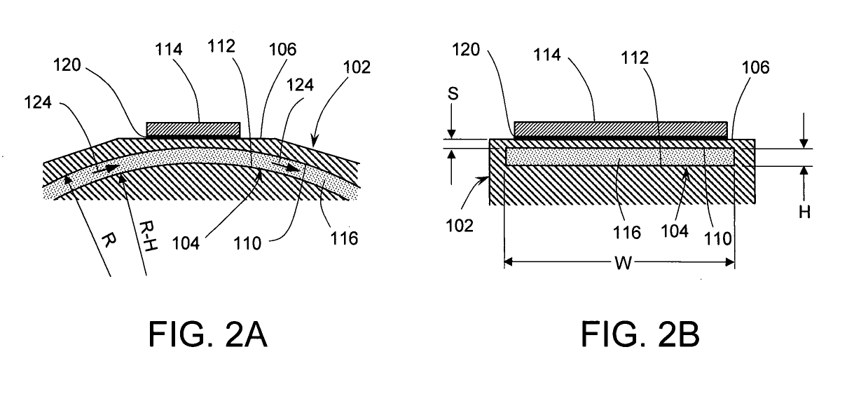

Referring now to FIGS. 2A and 2B, the HGC 114 may be thermally coupled to the first surface 106 with a suitable joining material 120. Preferably, joining material 120 has a good thermal conductivity. Suitable joining materials include solder, thermally conductive paste, epoxy, liquid metals, and adhesive. Alternatively, HGC 114 may be diffusion bonded onto surface 106. The flow channel 104 comprises an outer surface 110 and an inner surface 112. Each of the surfaces 110 and 112 may have a width “W” and they may be separated from each other by a distance “H”. Each of the surfaces 110 and 112 preferably has a constant radius of curvature “R” and “R-H”, respectively. For example, surfaces 110 and 112 may each be cylindrical and mutually concentric, thereby giving the flow channel 104 a general shape of a torus having a rectangular cross-section of width “W” and height “H”. Because the channel forms a closed loop, it may be also referred to in this disclosure as the “closed flow channel.” Preferred range for the width “W” is 0.1 to 20 millimeters, but dimensions outside this range may be also practiced. Preferred range for the radius of curvature “R” is 5 to 25 millimeters, but dimensions outside this range may be also practiced. Preferably, the distance “H” is chosen so that the channel 104 has a hydraulic diameter (=2 WH/(W+H)) about one to three millimeters, and most preferably about ten to micrometers to one millimeter. In addition, surfaces 110 and 112 should be made very smooth. Preferably, surfaces 110 and 112 are finished to surface roughness of less than 8 micrometers root-mean-square value, and most preferably to surface roughness of less than 1 micrometer root-mean-square value. Surfaces of the flow channel 104 may also have a coating to protect them from corrosion. The first surface 106 may be separated from the outer surface 110 by a distance “S” (FIG. 2B). Preferred range for the distance “S” is 0.1 to 1 millimeter, but dimensions outside this range may be also practiced.

The flow channel 104 contains a suitable electrically conductive liquid coolant 116. Preferably, the flow channel 104 is not entirely filled with the liquid coolant and at least some void space free of liquid coolant is provided inside the channel to allow for thermal expansion of the coolant. Preferably, the liquid coolant 116 has a good thermal conductivity, low viscosity, and low freezing point. Suitable liquid coolants 116 include selected liquid metals. For the purposes of this disclosure, the term “liquid metal” shall mean suitable metals (and their suitable alloys) that are in a liquid (molten) state at their operating temperature. Liquid metals have a comparably good thermal conductivity while being also electrically conductive and, in some cases have a relatively low viscosity. Examples of suitable liquid metals include mercury, gallium, indium, bismuth, and sodium. Examples of suitable liquid eutectic metal alloys include Indalloy 51 and Indalloy 60 (manufactured by Indium Corporation in Utica, N.Y.), and galinstan (obtainable from Geratherm Medical AG in Geschwenda, Germany). Galinstan is a nontoxic eutectic alloy of 68.5% by weight of gallium, 21.5% by weight of indium and 10% by weight of tin, having a melting point around minus 19 degrees Centigrade. It is important that electrodes 130a and 130b (FIG. 1B), and surfaces of the flow channel 104 are made of materials compatible with the coolant 116. In particular, it is well know that gallium and its alloys severely corrode many metals. Prior art indicates that certain refractory metals such as tantalum and tungsten may be stable in gallium. See, for example, “Effects of Gallium on Materials at Elevated Temperatures,” by W. D. Wilkinson, Argonne National Laboratory Report ANL-5027 (August 1953). To protect against corrosion, surfaces of the flow channel 104 may be coated with suitable protective film. Prior art indicates that TiN and certain organic coatings may be stable in gallium. If a protective coating is additionally dielectric, the body 102 may be constructed from electrically conductive materials.

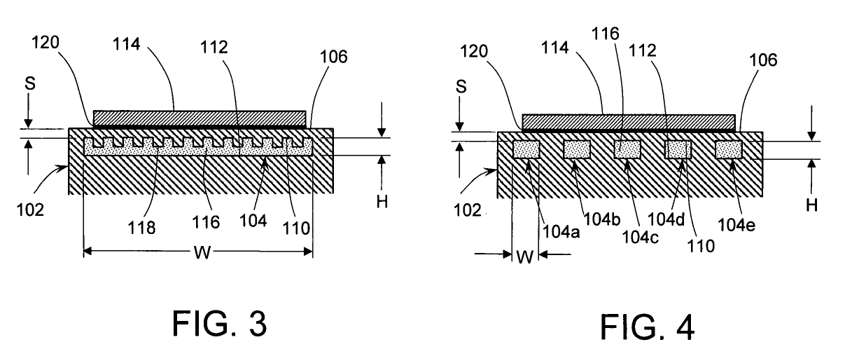

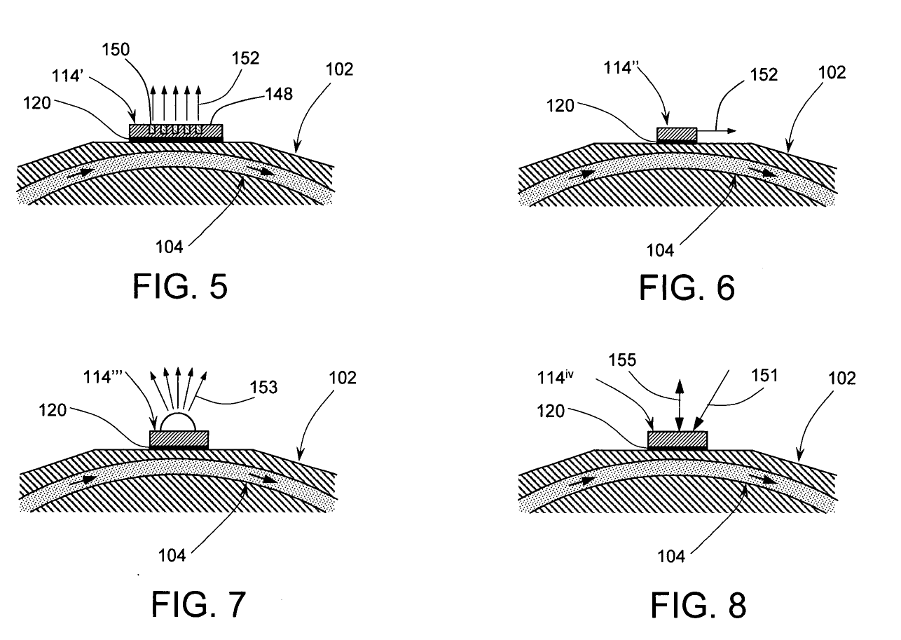

The outer surface 110 may also include extensions 118 to increase the contact area between the surface 110 and liquid coolant 116 (FIG. 3). Suitable form of surface extension 118 includes fins and ribs. Alternatively, multiple flow channels 104a-104e may be employed (FIG. 4). In some variants of the invention, a portion of the HGC 114 may form a portion of the outer surface 110 of the flow channel 104. FIG. 5 shows a mounting of HGC 114′, which is an array of semiconductor laser diodes (or laser diode bars) 150 imbedded in a substrate 148 and producing optical output 152. Suitable array of semiconductor laser diode bars imbedded in a substrate known as “silver bullet laser diode assembly submodule” and as “golden bullet laser diode assembly submodule” may be obtained from Northrop-Grumman Cutting Edge Optronics in St. Charles, MO. FIG. 6 shows a mounting of HGC 114″, which is a laser diode bar producing optical output 152. Suitable laser diode bar known as “unmounted laser diode bar” may be obtained from Northrop-Grumman Cutting Edge Optronics in St. Charles, Mo. FIG. 7 shows a mounting of HGC 114″′, which is a high-power light emitting diode producing optical output 153. Suitable high-power light emitting diode known as “Luxeon® K2” may be obtained from Philips Lumileds Lighting Company, Sun Valley, Calif.. FIG. 8 shows a mounting of HGC 114^{iv}, which is a solid-state laser crystal receiving optical pump radiation 151 and amplifying a laser beam 155. Suitable solid-state laser crystal may be in the form of a thin disk laser as, for example, described by Kafka et al., in the U.S. Pat. No. 7,003,011.

Referring now again to FIGS. 1A and 1B, the magnets 128a and 128b are arranged to generate magnetic field that traverses the flow channel 104 in the proximity of electrodes 130a and 130b in a substantially radial direction. Double arrow 160 indicates preferred directions of the magnetic field. Magnets 128a and 128b are preferably permanent magnets, and most preferably rare earth permanent magnets. Alternatively, magnets 128a and 128b may be formed as electromagnets. As a yet another alternative, magnets 128a and 128b may be pole extensions of a single magnet. Electrodes 130a and 130b are in electrical contact with the liquid coolant 116 and are arranged so that electric current may be passed through the coolant 116 in the region between the magnets 128a and 128b in a direction generally orthogonal to magnetic field direction. Electrodes 130a and 130b may be connected to external source of direct electric current via electric conductors 126a and 126b respectively. The HTD 100 may further include a magnetic shield (not shown) to prevent adverse effect of magnetic field generated by magnets 128a and 128b on HGC 114 and/or nearly components.

In operation, electric current is passed though the liquid coolant 116 between electrodes 130a and 130b. Because at least a portion of the coolant 116 is immersed in magnetic field orthogonal to the electric current flowing though the coolant 116, a magneto-hydrodynamic (MHD) effect causes the coolant 116 to flow in the direction indicated by the arrow 122 in FIG. 1A and the arrows 124 in FIG. 2A. As a result, flow of coolant 116 forms a closed flow loop. Because the closed flow loop has a substantially constant radius of curvature and the walls of the flow channel 104 are smooth, the flow of coolant 116 encounters relatively little resistance. As a result, very high flow velocities of coolant 116 can be sustained with a relatively small amount of motive power.

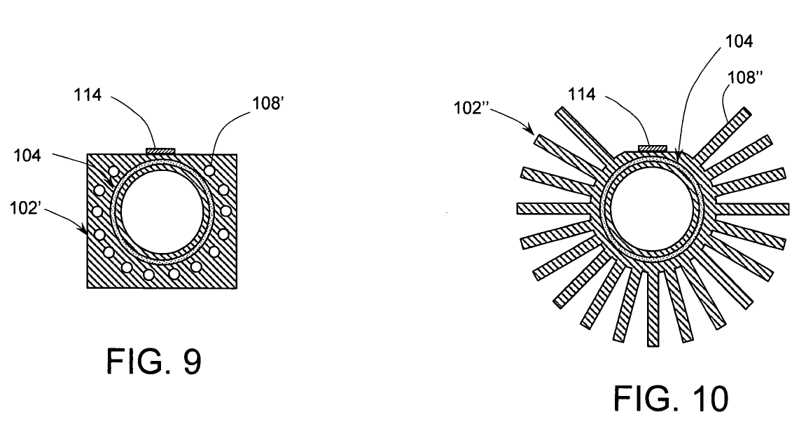

The HGC 114 is operated and its waste heat is allowed to transfer through the first surface 106 into the body 102 and conducted to the outer surface 110 of the flow channel 104. The second surface 108 is maintained at a temperature substantially below the temperature of the HGC 114. Liquid coolant 116 flowing at high velocity enables a very high heat transfer coefficient on the surface 110. Heat is transferred from the surface 110 into the liquid coolant 116, transported by the coolant 116, and deposited into other parts of the body 102. Heat deposited into other parts of the body 102 is conducted to the second surface 108 and transported therefrom to a suitable heat sink. Using the above process, HTD 100 removes heat from the HGC 114 and transfers it to a heat sink or environment. FIG. 9 shows an HTD body 102′ having a second surface 108′ formed as internal passages for flowing secondary liquid or gaseous coolant. FIG. 10 shows an HTD body 102″ having a second surface 108″ formed as external fins for transferring heat to gaseous coolant or ambient air.

Temperature of HGC 114 may be controlled by controlling the flow velocity of the coolant 116. The latter can be accomplished by controlling the current drawn through the coolant 116 via electrodes 130a and 130b. For example, by drawing more current through the coolant 116, the coolant flow velocity may be increased, and the HGC waste heat may be removed at a lower temperature differential between the HGC and the heat sink. Conversely, by drawing less current through the coolant 116, the coolant velocity may be decreased, and the HGC waste heat may be removed at a higher temperature differential between the HGC and the heat sink. Thus, by drawing more current through the coolant 116, the temperature of the HGC 114 may decreased, and by drawing less current through the coolant 116, the temperature of the HGC 114 may be increased. An automatic closed-loop temperature control of HGC 114 can be realized by sensing HGC temperature (for example, with a thermocouple) and using this information to appropriately control the current drawn through the coolant 116. In particular, if the HGC 114 is an LED, its temperature may be inferred from the output light spectrum. A means for sensing the LED light spectrum may be provided for this purpose. If the HGC 114 is a semiconductor laser diode, its temperature may be inferred from the output light center wavelength. A means for sensing the semiconductor laser diode output light center wavelength may be provided for this purpose. Alternatively, HGC temperature may be determined from certain current and/or voltages sensed in the HGC. If the coolant used in the HTD is susceptible to freezing (solidifying) due to ambient conditions during inactivity, the HTD may be equipped with an electric heater to warm the coolant up to at least its melting point.

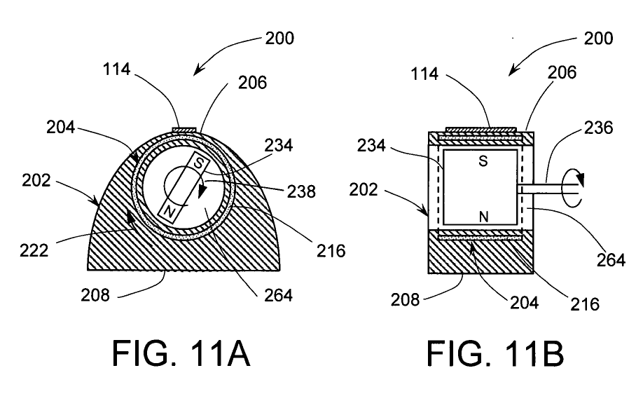

Referring now to FIGS. 11A and 11B, there is shown a heat transfer device (HTD) 200 in accordance with another preferred embodiment of the subject invention. HTD 200 is similar to HTD 100, except that in HTD 200 the coolant 216 inside the flow channel 204 may be an electrically conductive liquid or a ferrofluid. In addition, the flow of the coolant 216 is caused by a rotating magnetic field. The flow channel 204 in HTD 200 may be of the same construction as the flow channel 104 in HTD 100. Ferrofluids are composed of nanoscale ferromagnetic particles suspended in a carrier fluid, which may be water, an organic liquid, or other suitable liquid. Certain water-based ferrofluids such as W11 available from FerroTec in Bedford, N.H., are also electrically conductive. Ferrofluids using a liquid metal or liquid metal alloy as a carrier fluid have been reported in prior art; see, for example, an article by J. Popplewell and S. Charles in New Sci. 1980, 97 (1220), 332. The nano-particles are usually magnetite, hematite or some other compound containing iron and are typically on the order of about 10 nanometers in size. This is small enough for thermal agitation to disperse them evenly within a carrier fluid, and for them to contribute to the overall magnetic response of the fluid. The ferromagnetic nano-particles are coated with a surfactant to prevent their agglomeration (due to van der Waals and magnetic forces). Ferrofluids may display paramagnetism, and are often referred as being “superparamagnetic” due to their large magnetic susceptibility. Alternatively, liquid coolant 216 may comprise a liquid having significant paramagnetic, diamagnetic, or ferromagnetic properties.

The body 202 is similar to body 102 of HTD 100 (FIG. 1A) except that it has a round central opening 264. In addition, the magnets 128a and 128b, the electrodes 130a and 130b, and the electric conductors 126a and 126b (FIG. 1A) are omitted. The body 202 further comprises a first surface 206 adapted for receiving heat from HGC 114, a second surface 208 adapted for rejecting heat. Furthermore, the body 202 may be also constructed from a variety of (preferably non-ferromagnetic) materials preferably having high thermal conductivity. For example, the body 202 may be constructed from copper, copper-tungsten alloy, aluminum, molybdenum, silicon, and silicon carbide. Depending on the choice of coolant 216, the surfaces of the flow channel 204 may require appropriate protective coating to present corrosion. HTD 200 further comprises a magnet 234 rotatably suspended inside the opening 264 and positioned so that a significant portion of magnetic field lines cross the flow channel 204. The label “N” designates the north pole of the magnet and the label “S” designates the south pole of the magnet.

Operation of HTD 200 is similar to the operation of HTD 100 except that the flow of the coolant 216 is caused by different means than flow of the coolant 116 in HTD 100. In particular, magnet 234 is rotated in the direction of arrow 238 to generate a rotating magnetic field. The magnet 234 may be rotated mechanically by shaft 236 that may be coupled to an external drive such as electric motor. Alternatively, the magnet 234 may be rotated by means of a magnetic coupling to an external rotating ferromagnetic component. As another alternative, the magnet 234 may be rotated by a rotating magnetic field generated by electromagnets. As a yet another alternative, the magnet 234 may be rotated by a turbine operated by a secondary coolant flowing through the central opening 264.

If the coolant 216 is an electrically conductive liquid, time varying magnetic field produced by the rotation of the magnet 234 induces eddy currents in the electrically conductive coolant 216. Such eddy currents, interact with the rotating magnetic field produced by the magnet 234 thereby establishing a force coupling between the rotating magnet 234 and the coolant 216. As a result, rotating magnet 234 exerts a force onto the coolant 216 causing the coolant 216 to flow inside the flow channel 204 in the direction of the arrow 222 thereby forming a flow loop. Additional information about eddy current devices may be found in “Permanent Magnets in Theory and Practice,” chapter 7.6: Eddy-Current Devices, by Malcolm McCraig, published by Pentech Press, Plymouth, UK, 1977.

If the coolant 216 is a ferrofluid, magnetic field produced by the rotating magnet 234 directly couples into the coolant 216 and flows it inside the flow channel 104 in the direction of the arrow 222. Rotational speed of the magnet 234 may used to control the flow velocity of the coolant 216. Thus, controlling the rotational speed of the magnet 234 allows to control the rate of heat removal from the HGC 114 and thus to control the HGC temperature.

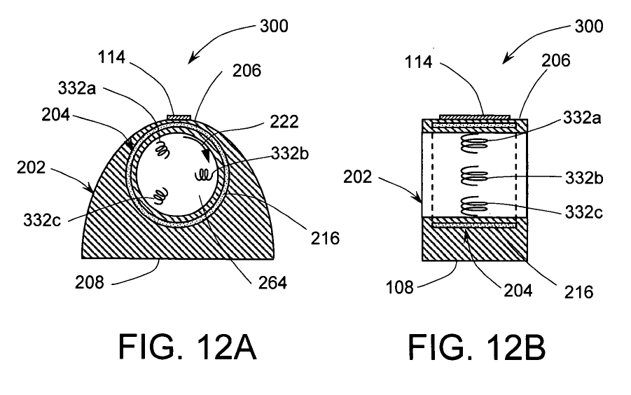

Referring now to FIGS. 12A and 12B, there is shown a heat transfer device (HTD) 300 in accordance with yet another preferred embodiment of the subject invention. HTD 300 is essentially the same as HTD 200, except that in HTD 300 the rotating magnetic field for flowing the liquid coolant 216 is generated by stationary electromagnet coils 332a, 332b, and 332c, rather than a rotating magnet 234. The coils 332a, 332b, and 332 are preferably installed inside the central opening 264 as shown in FIG. 4A, and supplied with poly-phase alternating electric currents. Phases of the alternating currents supplied to coils 332a, 332b, and 332c are set so that the combined magnetic field produced by the coils has a rotating component. For example, the electromagnet coils 332a, 332b, and 332c may be connected in a delta or star (Y) configuration as is often practiced in the art of three-phase alternating current systems (see, for example, “Standard Handbook for Electrical Engineers,” D. G. Fink, editor-in-chief, Section 2: Electric and Magnetic Systems, Three-Phase Systems, Tenth Edition, published by McGraw-Hill Book Company, New York, N.Y., 1968) and supplied with an ordinary three-phase alternating current. Rotating magnetic field couples into the coolant in an already described manner and causes the coolant 216 to flow around the closed loop.

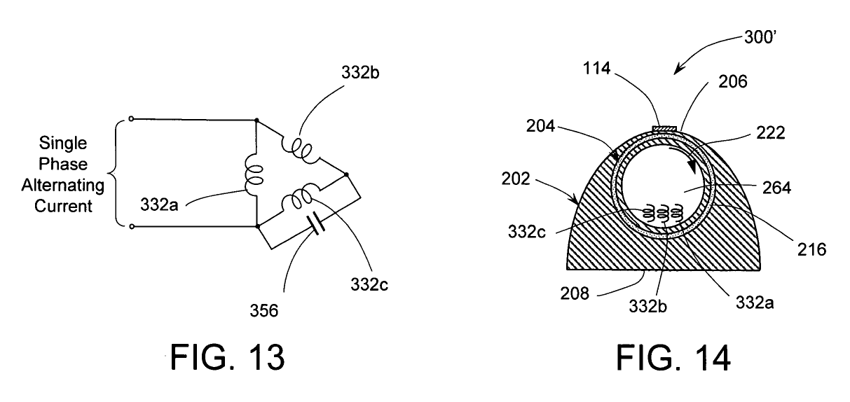

One skilled in the art can appreciate that there is a variety of electromagnet coil configurations fed by poly-phase alternating currents that can produce a time varying magnetic field with a rotating component (see, for example, “Magnetoelectric Devices, Transducers, Transformers, and Machines,” by Gordon D. Slemon, Chapter 5: Polyphase Machines, published by John Willey & Sons, New York, N.Y., 1966). Electromagnet coils may have ferromagnetic cores such as practiced on electric motors for alternating current. If only a single phase current is available, electromagnet coils 332a, 332b, and 332c may be combined with a capacitor 356 as shown, for example, in FIG. 13 to produce a suitable rotating magnetic field. There is a variety of similar connections practiced in the art of single phase electric motors. Frequency of the alternating currents supplied to the electromagnet coils 332a, 332b, and 332c may be used to control the flow velocity of the coolant 216. Thus, controlling the frequency of the alternating currents allows to control of the rate for heat removal from the HGC 114 and the HGC temperature. Typical range for alternating current frequency is from 1 to 1000 cycles per second. Alternatively, the coolant flow velocity may be controlled by controlling the electric current supplied to the electromagnets.

FIG. 14 shows an HTD 300′ that is a variant to the HTD 300 wherein the electromagnet coils 332a, 332b, and 332c are arranged to generate a traveling magnetic field rather than a rotating magnetic field. In particular, the electromagnet coils 332a, 332b, and 332c are arranged as often practiced in the art of linear electric motors and supplied with poly-phase alternating current in appropriate phase relationship. The resulting magnetic field is traveling generally in a linear path and it couples into the electrically conductive or ferrofluid coolant in the manner already described in connection with the HTD 300. It can be appreciated by those skilled in the art that the traveling magnetic field may cause the coolant 216 to flow even if the flow channel 204 may not have a substantially constant radius of curvature.

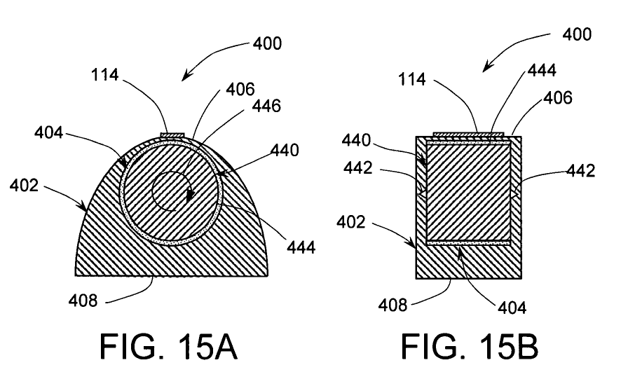

Referring now to FIGS. 15A and 15B, there is shown a heat transfer device (HTD) 400 in accordance with still another preferred embodiment of the subject invention. HTD 400 is similar to HTD 100, except that in HTD 400 the flow channel 404 is formed by a gap between the outer surface 410 of body 402 and a cylindrical surface 444 of an impeller 440. The impeller 440, which may have a shape of a cylinder is a rotatably suspended on bearings 442 and it may be magnetically or inductively coupled to external actuation means. Alternatively, the impeller may be driven by mechanical means. The body 402 further comprises a first surface 406 adapted for receiving heat from a heat generating component (HGC), a second surface 408 adapted for rejecting heat. The flow channel 404 contains a liquid coolant 416. The coolant 416 preferably has a good thermal conductivity and low viscosity. In operation, external actuation means may be used to spin the impeller 440. Due to its finite viscosity, at least a portion of the coolant 416 is entrained by the cylindrical surface 444 and travels with it, thereby establishing a flow loop. If desired, the cylindrical surface 444 may have surface extensions (for example, ridges, grooves, or surface irregularities) to better entrain the coolant. Rotational speed of the impeller 440 may be used to control the velocity of the coolant 416. Thus, controlling the rotational speed of the impeller 440 allows to control the HGC temperature.

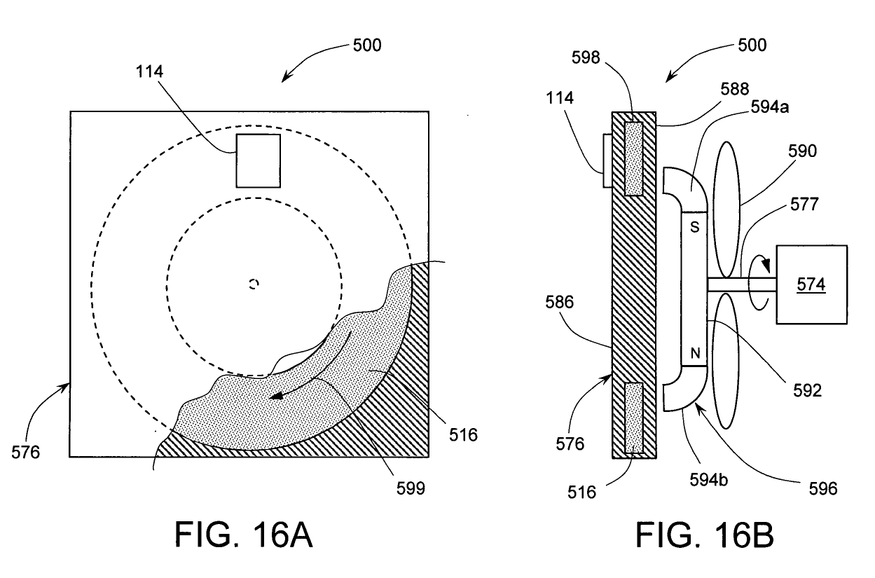

The HTD of the subject invention may be also practiced in a flat package. Referring now to FIGS. 16A and 16B, there is shown an HTD 500 in accordance with further preferred embodiment of the subject invention comprising a body 576 and a rotating magnet assembly 596. The body 576, which is preferably made of material having good thermal conductivity, is a generally flat member comprising a front face 586, back face 588, and an annular flow channel 598 therebetween. In one variant of the preferred embodiment, the channel 598 has a thickness in the range from 0.1 to 5 millimeters and an outside diameter in the range from 10 to 100 millimeters. The body is preferably constructed from materials having high thermal conductivity. Either one or both of the faces 586 and 588 may be in a thermal contact with a suitable heat sink. The channel 598 may be substantially filled with liquid coolant 516. The coolant 516 may be either an electrically conductive liquid and/or a ferrofluid. A heat-generating component (HGC) 114 may be attached to the front face 586 and arranged to be in a good thermal communication therewith. The magnet assembly 596 is rotationally suspended so that its plane of rotation is generally parallel to and in a close proximity to the back face 588. The magnet assembly 596 may also comprise a permanent magnet 592 and pole extensions 594a and 594b. Furthermore, the magnet assembly 596 may be affixed to a shaft 577 of an electric motor 574. A fan 590 may be also affixed to the shaft 577 of the electric motor 574.

In operation, the HGC 114 generates waste heat that is conducted to the front face 586 of the body 596 and, therethrough into the coolant 516. Electric motor 574 spins the magnet assembly 596, which generates a rotating magnetic field that penetrates though the back face 588 and interacts with the coolant 516. If the coolant 516 is electrically conductive, the rotating magnetic field couples to the coolant via eddy currents in a manner already describe in connection with the HTD 200. If the coolant 516 is a ferrofluid, the rotating magnetic field couples to the coolant magnetically in a manner already describe in connection with the HTD 200. In either case, rotation of the magnet assembly 596 causes the coolant 516 to flow around the annular flow channel 598 as indicated by the arrow 599. As a result, waste heat received by the coolant from HGC 514 is transported to other parts of the front face 586 and to the back face 588, and therefrom to a suitable heat sink. To facilitate improved removal of heat from the back face 588, fan 590 spun by electric motor may direct ambient air onto the back face 588. One skilled in the art will recognize that a rotating magnetic field suitable for causing the coolant 516 to flow around the annular flow channel 598 may be also produced by stationary electromagnets supplied with poly-phase alternating currents as already described in connection with the HTC 300.

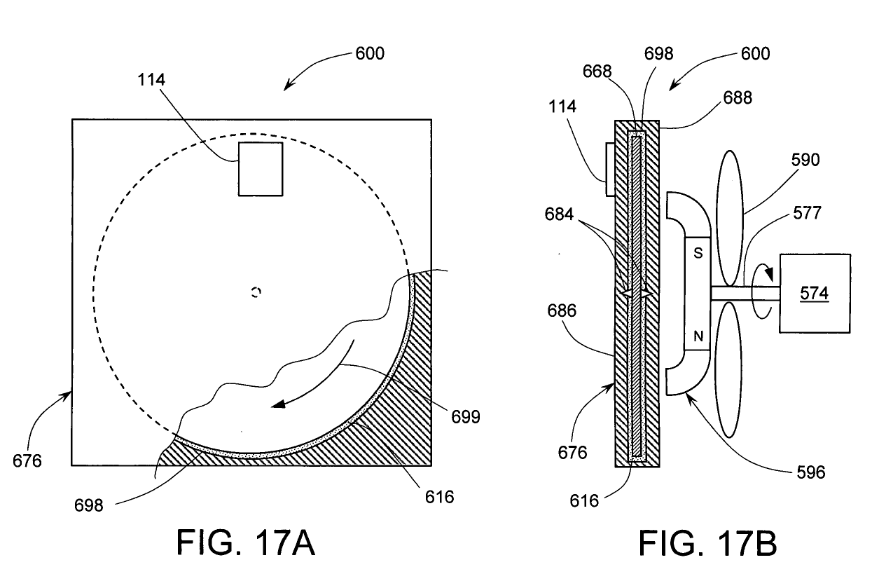

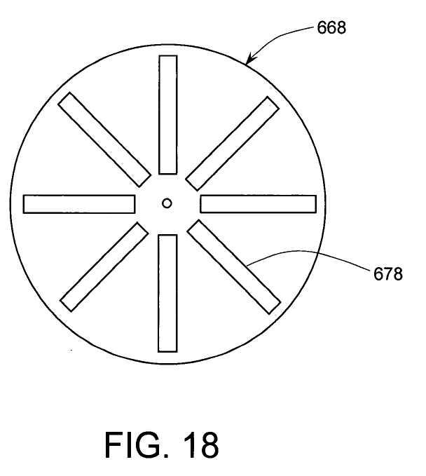

Referring now to FIGS. 17A and 17B, there is shown a heat transfer device (HTD) 600 in accordance with yet further preferred embodiment of the subject invention. The HTD 600 is essentially the same as the HTD 500, except that in HTD 600 further comprises an impeller disk 668. In addition, the flow channel 698 is a disk-like (rather than annular) cavity. Furthermore, the coolant 616 used with HTD 600 may be any suitable liquid coolant. The impeller disk 668 is rotatably suspended inside the flow channel 698 on bearings 684 and substantially immersed in coolant 616. The impeller disk 668 may be made of an electrically conductive material and/or from a ferromagnetic material. In some variants of this embodiment the impeller disk 668 may have radial slots or perforations 678 such as shown in FIG. 18 to improve inductive coupling to the rotating magnetic field. The HTD 600 operates similarly to the HTD 500, except that the rotating magnetic field generated by the magnet assembly 596 couples to the impeller disk 668. If the impeller disk 668 is made of an electrically conductive material such as copper, the magnetic field may couple into it inductively via eddy current interaction. If the impeller disk 668 is made of ferromagnetic material such as steel, the magnetic field may couple into it magnetically. In either case, rotation of the magnet assembly 596 causes the impeller disk 668 to rotate, which in turn causes the coolant 616 to flow inside the chamber 698 as indicated by arrow 699.

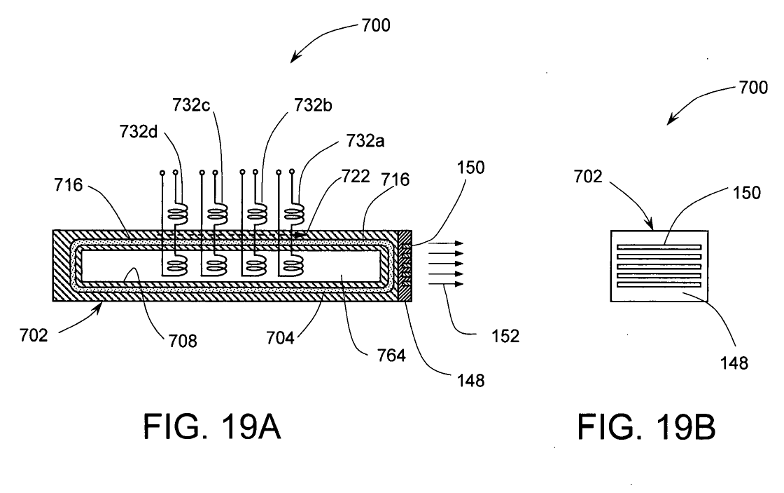

Referring now to FIGS. 19A and 19B, there is shown a heat transfer device (HTD) 700 in accordance with still further preferred embodiment of the subject invention and suitable for cooling semiconductor laser diode bars in densely packed arrays. HTD 700 is similar to HTD 300′, except that in HTD 700 the flow channel 704 and the opening 764 are elongated. In particular, the HTD 700 comprises a body 702 having an opening 764. A plurality of semiconductor laser diode 150 are installed into a substrate 148, which is attached to the body 702 and in a good communication therewith. The flow channel 704 containing liquid coolant 716 has a generally rectangular configuration, but other suitable configurations may be also practiced. Suitable liquid coolant 716 may be an electrically conductive liquid or a ferrofluid. Coil assemblies 732a-d each comprise two coils, one on the outside the body 702 and one inside the opening 764. Preferably, the coils in each assembly are positioned so that the magnetic field they generate crosses the channel 704 at substantially normal incidence. The coil assemblies 732a-d are fed poly-phase alternating currents arranged to produce magnetic field traveling in the direction of arrow 722, thereby inducing the coolant 716 to flow inside the channel 704 in the same direction. The laser diodes 150 are operated to produce optical output 152 while also generating waste heat. The coolant 716 flowing inside the channel 704 removes waste heat from the laser diodes 150 and transfers it to second surface 708 inside the opening 764. The opening may contain suitable heat sink such as secondary liquid coolant, gaseous coolant, or phase change material. It can be appreciated that the HTD 700 is conducive to stacking of multiple HTD units vertically and horizontally to produce large arrays that may be required for direct material processing or pumping of solid-state lasers.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” and “includes” and/or “including” when used in this specification, specify the presence of stated features, integers, steps, operations, elements, and/or components, but do not preclude the presence or addition of one or more other features, integers, steps, operations, elements, components, and/or groups thereof.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

The term “suitable,” as used herein, means having characteristics that are sufficient to produce a desired result. Suitability for the intended purpose can be determined by one of ordinary skill in the art using only routine experimentation.

Moreover, terms that are expressed as “means-plus function” in the claims should include any structure that can be utilized to carry out the function of that part of the present invention. In addition, the term “configured” as used herein to describe a component, section or part of a device includes hardware and/or software that is constructed and/or programmed to carry out the desired function.

Different aspects of the invention may be combined in any suitable way.

While only selected embodiments have been chosen to illustrate the present invention, it will be apparent to those skilled in the art from this disclosure that various changes and modifications can be made herein without departing from the scope of the present invention as defined in the appended claims. Furthermore, the foregoing description of the embodiments according to the present invention are provided for illustration only, and not for the purpose of limiting the present invention as defined by the appended claims and their equivalents. Thus, the scope of the present invention is not limited to the disclosed embodiments.

What is claimed is:

1. A heat transfer device comprising:
a) a body having a first surface, a second surface, and a closed flow channel;
said first surface being adapted for receiving heat from a heat generating component;
said second surface being adapted for transferring heat to a heat sink;
said flow channel having a substantially constant radius of curvature in the flow direction;
b) a liquid coolant flowing inside said closed flow channel; said liquid coolant being selected from the group consisting of a ferrofluid and electrically conductive liquid; and
c) a means for producing a moving magnetic field; said magnetic field arranged to operatively couple into said liquid coolant and flow said liquid coolant inside said flow channel.

2. The heat transfer device of claim 1, wherein said flow channel has a hydraulic diameter between 10 and about 500 micrometers.

3. The heat transfer device of claim 1, wherein said flow channel has a hydraulic diameter between about 0.5 and 3 millimeters.

4. The heat transfer device of claim 1, wherein said means for producing said moving magnetic field comprise a plurality of electromagnets fed with poly-phase alternating currents.

5. The heat transfer device of claim 1, wherein said means for producing a moving magnetic field comprise a rotating magnet.

6. The heat transfer device of claim 1, wherein said electrically conductive liquid is a liquid metal.

7. The heat transfer device of claim 1, wherein said flow channel includes surface extensions for enhancing heat transfer between the liquid coolant the material of said body.

8. A heat transfer device comprising:
a) a body having a first surface, a second surface, and a closed flow channel;
said first surface being adapted for receiving heat from a heat generating component;
said second surface being adapted for transferring heat to a heat sink;
said flow channel having a substantially constant radius of curvature in the flow direction;
b) a liquid coolant flowing inside said closed flow channel; and
c) an impeller adapted for flowing said liquid coolant inside said flow channel.

9. The heat transfer device of claim 8, wherein said impeller is operated by magnetic forces.

10. The heat transfer device of claim 8, wherein said impeller is operated by electromagnetic induction.

11. An apparatus for transferring heat from a heat generating component to a heat sink comprising:
a) a body having a first surface being adapted for receiving heat from a heat generating component, a second surface being adapted for transferring heat to a heat sink, and a flow channel formed within said body;
at least one portion of said flow channel being in a good thermal communication with said first surface;
at least one portion of said flow channel being in a good thermal communication with said second surface;
b) a liquid coolant flowing inside said flow channel; said liquid coolant comprising a liquid metal; and
c) a means for generating a moving magnetic field; said means arranged to inductively couple said magnetic field into said liquid coolant to flow said liquid coolant inside said flow channel.

12. The apparatus of claim 11, wherein said means for generating said moving magnetic field comprise a plurality of electromagnets fed with poly-phase alternating currents.

13. The apparatus of claim 12, wherein said poly-phase alternating currents are produced from a single phase alternating current.

14. The apparatus of claim 11, wherein said means for generating said moving magnetic field comprise a rotating magnet.

15. The apparatus of claim 11, further comprising an electric heater adapted for heating said liquid metal coolant up to at least its melting point.

16. The apparatus of claim 11, further comprising a means for controlling the flow speed of said liquid coolant inside said flow channel.

17. The apparatus of claim 11, wherein said flow channel has a substantially constant radius of curvature in the flow direction.

18. The apparatus of claim 11, wherein said moving magnetic field is a substantially traveling magnetic field.

19. The apparatus of claim 11, wherein said moving magnetic field is a substantially rotating magnetic field.

20. The apparatus of claim 11, wherein said flow channel has a hydraulic diameter between 10 and about 1000 micrometers.

21. The apparatus of claim 11, wherein said liquid metal coolant comprises a metal selected from the group consisting of gallium, indium, bismuth, mercury, and sodium.

22. A light emitting diode assembly comprising:
a) a light emitting diode;
b) a body having a first surface being adapted for receiving heat from said light emitting diode, a second surface being adapted for transferring heat to a ambient air, and a closed flow channel within said body;
said light emitting diode being in a good thermal communication with said first surface;
at least one portion of said flow channel being in a good thermal communication with said first surface;
at least one portion of said flow channel being in a good thermal communication with said second surface;
c) a liquid coolant flowing inside said closed flow channel; said liquid coolant being selected from the group consisting of a ferrofluid, galinstan, and liquid metal; and
d) a plurality of electromagnets fed with poly-phase alternating currents; said electromagnets and said poly-phase currents being arranged to generate a moving magnetic field; said moving magnetic field arranged to operatively couple into said liquid coolant to flow said liquid coolant around said closed flow channel.

23. The light emitting diode assembly of claim 22, wherein said poly-phase alternating current is produced from a single phase alternating current.

24. The light emitting diode assembly of claim 22, wherein the temperature of said light emitting diode is controlled by controlling the flow velocity of said liquid coolant flowing around said closed flow channel.

25. The light emitting diode assembly of claim 22, further comprising a means for sensing the color spectrum of the light produced by said light emitting diode.

26. The light emitting diode assembly of claim 22, wherein said flow channel has a substantially constant radius of curvature in the direction of the flow.

27. The light emitting diode assembly of claim 22, wherein said flow channel has a hydraulic diameter between 10 and about 1000 micrometers.

28. A semiconductor laser diode assembly comprising:
a) a semiconductor laser diode;
b) a body having a first surface being adapted for receiving heat from said semiconductor laser diode, a second surface being adapted for transferring heat to a heat sink, and a closed flow channel within said body;
said semiconductor laser diode being in a good thermal communication with said first surface;
at least one portion of said flow channel being in a good thermal communication with said first surface;
at least one portion of said flow channel being in a good thermal communication with said second surface;
c) a liquid coolant flowing inside said closed flow channel; said liquid coolant being a liquid metal; and
d) a means for flowing said liquid coolant inside said flow channel; said means selected from the group consisting of magnetohydrodynamic means and inductive means.

29. The semiconductor laser diode assembly of claim 28, wherein:
said inductive means for flowing said liquid coolant around said flow channel comprise a plurality of electromagnets fed with poly-phase alternating currents;
said electromagnets and said poly-phase alternating current being arranged to generate a moving magnetic field; and
said moving magnetic field being arranged to inductively couple into said liquid coolant to flow said liquid coolant inside said closed flow channel.

30. The semiconductor laser diode assembly of claim 28, wherein said magnetohydrodynamic means for flowing said liquid coolant around said flow channel comprise a plurality of electrodes for drawing electric current through said liquid metal coolant and a magnet.

31. The semiconductor laser diode assembly of claim 28, wherein the temperature of said semiconductor laser diode is controlled by controlling the flow velocity of said liquid coolant flowing around said closed flow channel.

32. The semiconductor laser diode assembly of claim 28, wherein said flow channel has a hydraulic diameter between 10 and about 1000 micrometers.

33. The semiconductor laser diode assembly of claim 28, wherein said flow channel includes surface extensions for enhancing heat transfer between the liquid coolant the material of said body.

34. The semiconductor laser diode assembly of claim 28, further comprising a means for sensing the center wavelength of the light produced by said semiconductor laser diode.

35. The semiconductor laser diode assembly of claim 28, wherein said heat sink is selected from the group consisting a heat pipe, secondary liquid coolant, phase change material, and ambient air.

36. The semiconductor laser diode assembly of claim 28, wherein said flow channel has a substantially constant radius of curvature in the direction of the flow.

37. A semiconductor electronic chip assembly comprising:
a) a semiconductor electronic chip;
b) a body having a first surface being adapted for receiving heat from said semiconductor chip, a second surface being adapted for transferring heat to a heat sink, and a closed flow channel within said body;
said semiconductor electronic chip being in a good thermal communication with said first surface;
at least one portion of said flow channel being in a good thermal communication with said first surface;
at least one portion of said flow channel being in a good thermal communication with said second surface;
said flow channel having a substantially constant radius of curvature in the direction of the flow;
c) a liquid coolant flowing inside said closed flow channel; said liquid coolant being selected from the group consisting of a ferrofluid, galinstan, and liquid metal; and
d) a means for generating a moving magnetic field; said means arranged to operatively couple said magnetic field into said liquid coolant to flow said liquid coolant inside said closed flow channel.

38. The semiconductor electronic chip assembly of claim 37, wherein:
said means for generating a moving magnetic field comprises a plurality of electromagnets fed with poly-phase alternating currents;
said electromagnets and said poly-phase being arranged to generate a moving magnetic field; and
said moving magnetic field arranged to operatively couple into said liquid coolant to flow said liquid coolant around said closed flow channel.

39. The semiconductor electronic chip assembly of claim 37, wherein said means for generating a moving magnetic field comprise a rotating magnet.

40. The semiconductor electronic chip assembly of claim 37, further comprising a fan directing ambient air onto said second surface.

41. The semiconductor electronic chip assembly of claim 37, wherein said heat sink is selected from the group consisting of a structure, heat pipe, secondary liquid coolant, phase change material (PCM), gaseous coolant, and ambient air.

42. A method for cooling a heat generating component comprising the acts of:
a) providing a body having a first surface, a second surface, and a closed flow channel within said body; at least one portion of said flow channel being in a good thermal communication with said first surface; and at least one portion of said flow channel being in a good thermal communication with said second surface;
b) providing a heat generating component being in a good thermal communication with said first surface;
c) providing a heat sink in a good thermal communication with said second surface;
d) providing a liquid coolant inside said closed flow channel; said coolant selected from the group consisting a ferrofluid and liquid metal;
e) generating a moving magnetic field;
f) operatively coupling said moving magnetic field into said liquid coolant;
g) inducing said liquid coolant to flow inside said closed flow channel;
h) operating a heat generating component to generate waste heat;
i) transferring said waste heat from said heat generating component to said coolant; and
j) transferring said waste heat from said liquid coolant to said heat sink.
The method of claim 42, wherein said moving magnetic field is produced by a plurality of electromagnets fed with poly-phase alternating currents.

43. The method of claim 42, wherein said moving magnetic field is produced by a rotating magnet.

44. The method of claim 42, wherein said flow channel has a substantially constant radius of curvature in the direction of the flow.
